(19) United States
(12) Patent Application Publication
(10) Pub. No.: US 2017/0309577 A1
(43) Pub. Date: Oct. 26, 2017

(54) METHOD OF MANUFACTURING SEMICONDUCTOR DEVICES

(71) Applicant: Infineon Technologies AG, Neubiberg (DE)

(72) Inventor: Markus Brunnbauer, Lappersdorf (DE)

(73) Assignee: Infineon Technologies AG, Neubiberg (DE)

(21) Appl. No.: 15/137,396

(22) Filed: Apr. 25, 2016

(51) Int. Cl. H01L 23/00; H01L 21/3205; H01L 21/308; H01L 23/58; H01L 21/306

(52) U.S. Cl. CPC H01L 23/562; H01L 23/585; H01L 21/30625; H01L 21/308; H01L 21/32051

(57) ABSTRACT

A method for use in manufacturing semiconductor devices includes providing a wafer includes a semiconductor substrate that is mechanically homogeneous. The method further comprises forming a mechanical structure in the semiconductor substrate. In a wafer comprising a semiconductor device on a semiconductor substrate, the semiconductor substrate includes a mechanical structure. In a die comprising a semiconductor device on a semiconductor substrate, the semiconductor substrate includes a mechanical structure.

The present application relates to a method of manufacturing semiconductor devices.

### BACKGROUND

Thin wafers that are used to manufacture semiconductor devices are prone to bending. With wafer manufacturing processes, in particular, during dicing of the wafer, bending of the wafer can cause significant problems.

### SUMMARY

According to an embodiment of a method, the method includes providing a semiconductor substrate that is mechanically homogeneous, and forming a mechanical structure in the substrate.

According to an embodiment of a wafer, the wafer includes a semiconductor device on a semiconductor substrate, and the substrate includes a mechanical structure.

According to an embodiment of a die, the die includes a semiconductor device on a semiconductor substrate, and the semiconductor substrate includes a mechanical structure.

### BRIEF DESCRIPTION OF THE DRAWINGS

Objects and features of the techniques disclosed herein will become apparent from the following description of exemplary embodiments and exemplary embodiments with reference to the following figures, wherein like reference numerals refer to like parts throughout the various figures unless otherwise specified.

FIG. 1 illustrates an embodiment of a method of manufacturing semiconductor devices.

FIGS. 2A-2H illustrate cross-sectional views of an embodiment of a method of forming a semiconductor substrate.

The illustrated structures and/or devices are not necessarily drawn to scale.

### DETAILED DESCRIPTION

Below embodiments, implementations and associated effects are disclosed with reference to the accompanying drawings. As used herein, like terms refer to like elements throughout the description.

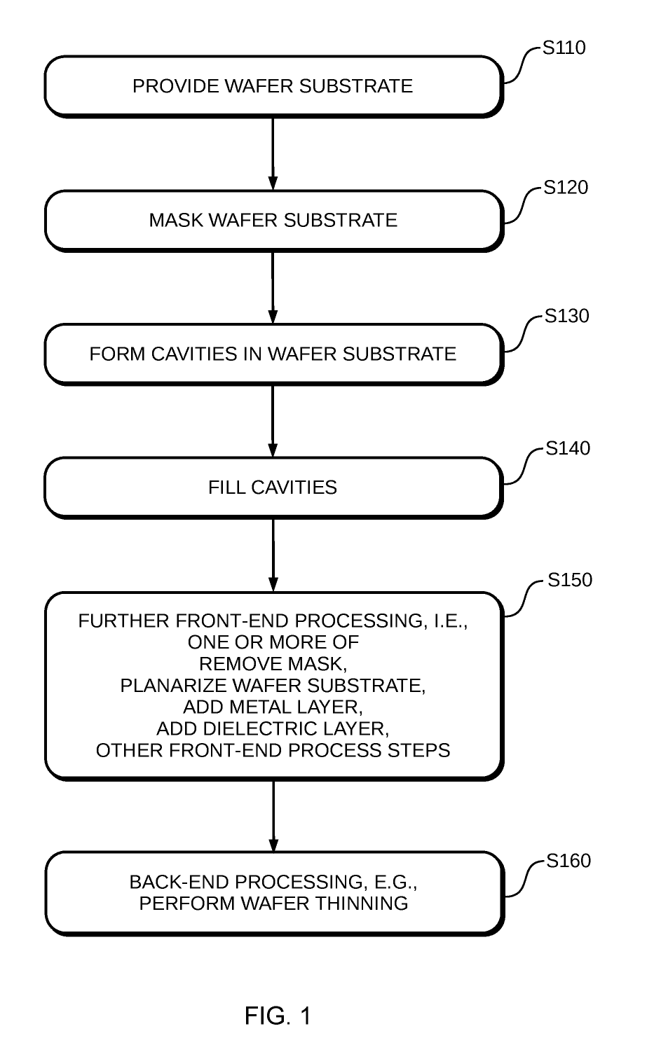

FIG. 1 is a diagram that schematically illustrates a flowchart of a method according to some embodiments. The method can be used for manufacturing semiconductor devices. In some embodiments, a plurality of semiconductor device structures provided on a wafer substrate form a portion of a corresponding plurality of integrated circuits to be manufactured on the wafer substrate. For example, the semiconductor device chips can each include one or more integrated circuits. In some embodiments, the semiconductor device includes a power transistor. In some embodiments the semiconductor device includes a micro-electrical-mechanical element or micro-electrical-mechanical system (MEMS). For example, the semiconductor device can include a mechanical sensor element such as a pressure sensor element. In some embodiments, at least two of the aforementioned elements are combined in the semiconductor device chip.

Generally, the method comprises providing a wafer that includes a semiconductor substrate that is mechanically homogeneous. The method further includes forming a mechanical structure in the semiconductor substrate.

At S110, in an exemplary embodiment, a wafer is provided that includes a substrate. In the illustrated embodiments, the substrate is mechanically homogeneous. In some embodiments, the substrate is crystalline. In some embodiments, the substrate is monocrystalline. The substrate may include defects, in particular lattice defects. The substrate may also include impurities. In particular, the substrate may be doped, for example, having at a surface of the substrate, n-wells and/or p-wells. The substrate may include other chemical inhomogeneity. In other words, though the lattice of the substrate may be defective and some portions of the substrate may include impurities of different kinds and levels, while mechanically on a macroscopic scale, the substrate is homogeneous. For example, a module of elasticity is represented by a tensor that is constant throughout the substrate. In some embodiments, the wafer includes a reinforcement, for example, a so-called Taiko ring formed on an edge of the wafer that strengthens the wafer and/or holds the substrate.

At S120, in some embodiments, the method comprises forming a mask layer over the substrate. In some embodiments, the mask layer is provided using a photolithography technique. The mask layer has openings, i.e., the mask layer is structured or patterned. For example, the mask layer can include a plurality of trenches arranged in parallel and/or orthogonally. In some embodiments, the trenches are arranged in a hexagonal ‘honeycomb’ pattern. The skilled person can contemplate other arrangements. In one embodiment, the mask is designed taking account of other structural elements such as crack stops to be formed on the substrate in addition to the structural elements to be formed in the substrate based on the present mask.

At S130, the mask layer is exposed to an etchant. In some embodiments, the etchant is a wet etchant. In some embodiments, the etchant is a dry etchant such as a plasma etch. Thus, via the openings in the mask layer, where the surface of the substrate of the wafer is exposed to the etchant and/or the plasma, the etchant is applied to the substrate. In some embodiments, the etchant is a wet etchant that can enter the opening in the mask layer and etch from a floor of the opening, i.e., the substrate surface down into the substrate. In some embodiments, a plasma etch is performed. At least one effect of the etching can be that, in the substrate, a cavity or a plurality of cavities are formed. The cavities replicate the structure or pattern of the mask layer. Though not shown in FIG. 1, after applying the etchant and having the etchant work its way into the substrate, in some embodiments, the patterned mask layer is removed. Further, the wafer can be cleaned, in particular to remove remainders of the mask layer, and to remove the etchant and/or any debris or other reaction products formed during etching. In other embodiments, two or more etching steps that are based on a variety of etching techniques can be applied. The skilled person can be guided by many considerations, such as a pattern of cavities that are to be formed, available etching techniques, and an amount of time required to complete the etching.

At S140, a substance is deposited in the plurality of cavities. The plurality of cavities in the substrate are filled with the substance. Structural characteristics of the substance, in particular mechanical characteristics, differ from those of the substrate. In some embodiments, epitaxy or epitaxial deposition is used to provide the substance in the cavities. In some embodiments, selective ion implantation is used to provide the substance in the cavities. In some embodiments, a damascene process is performed to provide the substance in the cavities. It should be understood that the act of filling is not limited to deposition of a single substance in the cavities. In some embodiments, in a first step, a barrier layer of a barrier substance such as titanium or titanium nitride may be applied to the cavities before a second step where the cavities are filled with the substance. In one embodiment, the substance is copper. At least one effect can be that the formerly homogeneous substrate is now provided with a structure. In particular, the substrate includes a mechanical structure.

At S150, in some embodiments, after having completed the formation of the mechanical structure in the substrate, other processing steps are performed. In particular, the wafer can be subjected to front-end processing steps such as removing the mask layer if the mask layer was not removed during prior steps. The wafer can be planarized, for example, by performing chemical mechanical polishing. In some embodiments, a metal layer is added, for example, to form metal lines therefrom. In some embodiments, a dielectric layer is added. In particular, the dielectric layer can be added over a wafer surface that has the mechanical structure. Thus, for example, integrated circuit elements and conductor lines can safely be included. It should be understood that a plurality of metal and/or dielectric layers can be added as needed to form the semiconductor device based on the wafer substrate. Other front-end processes can be performed as needed.

At S160, further processing steps are performed. In particular, the wafer can be subjected to back-end processing steps such as wafer thinning. For example, the wafer is subjected to mechanical grinding. In some embodiments, a first support layer such as grinding support tape can be provided, in particular, prior to performing the wafer thinning. At least one effect can be that the wafer, during the grinding, is less prone to damage, since the wafer is strengthened by the first support layer. In some embodiments, the first support layer is provided on a face of the wafer that is close to the mechanical structure. In some embodiments, the thinning is performed at a wafer face that is distant from the mechanical structure. In some embodiments, the wafer is washed, for example, with deionized water such that a risk of contamination of the wafer with ions is reduced while removing debris from the wafer. As an alternative to grinding, or in addition to grinding, in order to thin the wafer, another technique such as chemical mechanical polishing, wet etching, atmospheric downstream plasma and dry chemical etching can also be used. In various embodiments, a thickness of the wafer is reduced to a thickness that is less than 100 μm. In some embodiments, a thickness of the wafer is reduced to be within a range of 50 μm to 80 μm. In some embodiments, a thickness of the wafer is reduced to be within a range of 10 m to 50 μm. In some embodiments, a thickness of the wafer is reduced to be within a range of 15 μm to 30 μm. In some embodiments, after the wafer is thinned, a second support layer is added to the substrate. For example, in one embodiment, a metallization layer is formed on a face or surface of the substrate that was thinned.

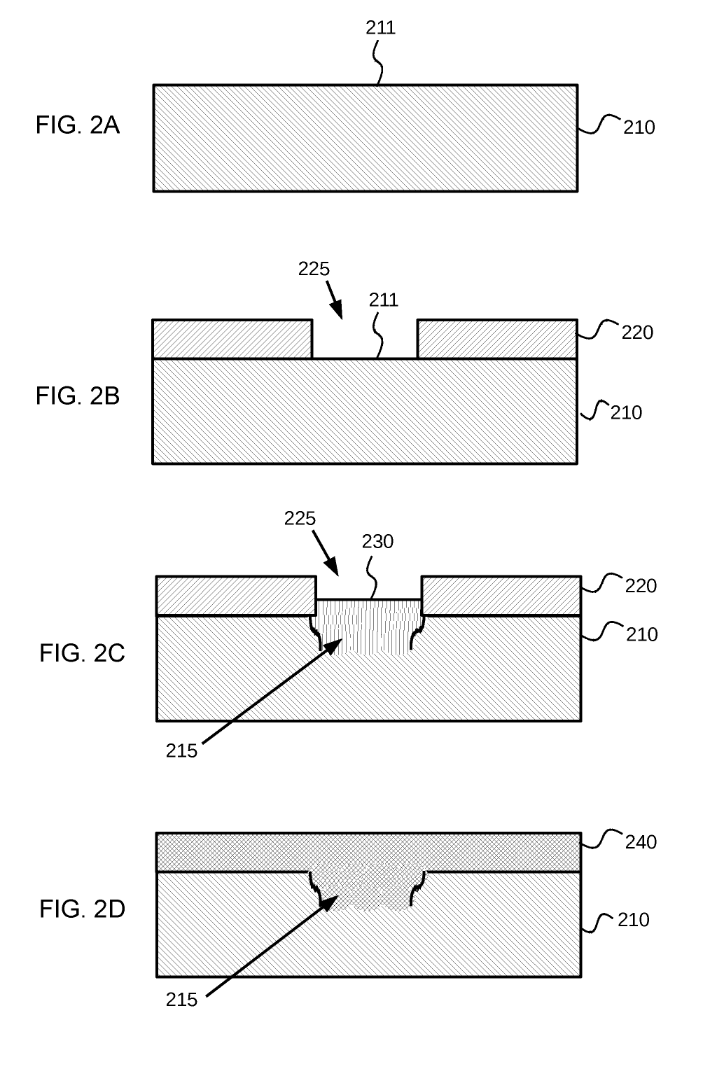

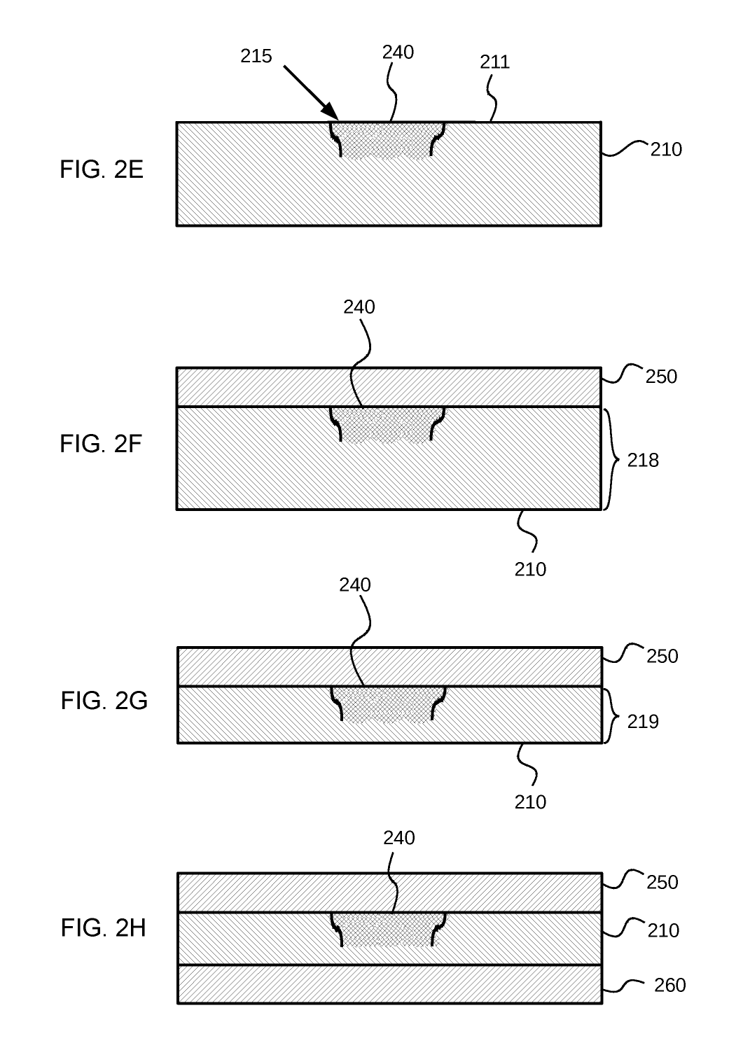

FIGS. 2A-2H illustrate cross-sectional views of an embodiment of a method of forming a semiconductor substrate. As illustrated in FIG. 2A, an exemplary embodiment of a semiconductor wafer comprises a substrate 210. In the illustrated embodiment, the substrate 210 has a planar surface 211. However, in some embodiments (not shown), the wafer is non-planar. For example, the wafer can include a reinforcement such as a so-called Taiko ring formed on an edge of the wafer that is thicker than the substrate and strengthens the wafer. In some embodiments, the surface of the substrate that is surrounded by the Taiko ring is planar. In some embodiments, the surface of the substrate is not planar. For example, in some embodiments, a semiconductor device structure can be formed on at least a portion of the wafer substrate. In some embodiments, the illustrated methods are performed after some structural build-up is completed on the wafer substrate.

As illustrated in FIG. 2B, an exemplary embodiment of a semiconductor wafer at one stage of an exemplary process comprises a mask layer 220. For example, the mask can be provided as a positive resist mask or as a negative resist mask. Other examples include an oxide hard mask. In still other embodiments, the mask layer 220 is provided as a nitride mask. The mask layer 220 is structured. For example, the mask layer 220 can be provided with openings 225 such as trenches adapted to receive a substance in further processing steps such as to receive an etchant. It should be understood that although a single opening 225 is shown, in other embodiments, the mask can include two or more openings. In some embodiments, the openings are adapted to receive an etchant. In the embodiment shown in FIG. 2B, the opening goes all the way through the mask layer 220 such that the surface 211 of the substrate can be exposed through the opening to an etchant or other substance that is deposited atop the substrate in a subsequent process step.

As illustrated in FIG. 2C, an etchant 230 is applied to the wafer substrate 210. For example, the etchant 230 is a wet etch that enters the opening 225 within the mask layer 220 and etches from a floor of the opening, i.e., the substrate surface 211, down into the substrate 210 to form a cavity 215. In some embodiments, cavity 215 is a trench with substrate 210.

As illustrated in FIG. 2D, a substance 240 whose structural characteristics, in particular whose mechanical characteristics, differ from those of the material of the substrate 210, is provided on the wafer substrate 210. In some embodiments, a mechanical property of substance 240 has a value that is different than the value of the mechanical property of substrate 210. In some embodiments, the substance 240 also fills the cavity 215.

As illustrated in FIG. 2E, in some embodiments, excess substance 240 is removed from the wafer substrate 210. For example, as described above with reference to the process flow illustrated in FIG. 1, chemical mechanical polishing and/or wafer cleaning may be performed. In one embodiment, only the cavity 215 includes the substance 240. The substrate 210 exposes the planar surface 211, albeit including a portion that includes the substance 240. The substrate illustrated in FIG. 2E merely shows an exemplary portion of the wafer. It should therefore be understood that the wafer can include a plurality of cavities 215 such as trenches that together form a pattern, net and/or grid in the substrate 210 and that are filled with the substance 240.

Structural characteristics of the substance 240, in particular, mechanical characteristics or mechanical properties of the substance 240, are different than the mechanical characteristics or mechanical properties of the substrate 210. In one embodiment, a value of a coefficient or tensor of expansion of the substance 240, i.e., an expansion of volume with temperature, is different than a value of a coefficient or tensor of expansion of the substrate 210. A coefficient of expansion can be measured, for example, macroscopically by using laser interferometry. In some examples, a module of elasticity of the substance 240 differs from the module of elasticity of the material of the substrate 210. In one example, where the substrate 210 is provided as an essentially monocrystalline semiconductor, the substance 240 can be copper or another metal that is more elastic than the monocrystalline semiconductor. For example, for substrate 210, in some embodiments, a coefficient of elasticity can be less than 1%. In some embodiments, the coefficient of elasticity can be less than 1 per mille. In some embodiments, the elasticity of substance 240 provided in cavity 215 has a coefficient of elasticity that is within a range of 2% to 5%, which is greater than the coefficient of elasticity of the substrate which is less than 1%. A measurement of the coefficient of elasticity can be performed, for example, by using a microscopic method such as a measurement of nanoindentation.

In one embodiment, substance 240 in cavities 215 forms a grid that can dissipate stress and/or compensate. In another embodiment, the wafer including the grid becomes more rigid and thus less prone to bending. In particular, the mechanical benefit of the added structure in the substrate is better stress mitigation than with the homogeneous substrate. Thus, the mechanical structure in the substrate can improve the wafers capability to cope with stress such as thermal stress induced by subsequent process steps.

In various embodiments, a wafer that undergoes frontend processing as described above includes a semiconductor device on a semiconductor substrate, where the semiconductor substrate includes a mechanical structure. In some embodiments, the semiconductor substrate includes a first plurality of crystalline semiconductor portions and a second plurality of other portions that differ from the first plurality of crystalline semiconductor portions in respect to a mechanical property or a value of a mechanical property. In some embodiments, the second plurality of other portions forms the mechanical structure in the semiconductor substrate. In some embodiments, the semiconductor device comprises at least one circuit element. The at least one circuit element is separate from the plurality of other portions.

As illustrated in FIG. 2F, in some embodiments, after having performed other frontend processes on substrate 210 to form one or more semiconductor devices (not illustrated in FIGS. 2A to 2H), a first support layer 250 is provided on top of the substrate 210. In some embodiments, the first support layer 250 is permanent, while in other embodiments, the first support layer 250 is removable. For example, in one embodiment, the first support layer 250 is provided as metal, while in another embodiment, the first support layer 250 is provided by back grinding tape. In some embodiments, the back grinding tape can be cured. In these embodiments, the wafer is more resilient and less prone to breaking, in particular during thinning. At this stage, a first thickness 218 of the substrate 210 should be noted.

As illustrated in FIG. 2G, the wafer undergoes thinning of the substrate 210. After thinning, the substrate 210 has a second thickness 219 that is less than the first thickness 218. In one embodiment (not shown in FIG. 2G), the thinning is performed to an extent that the structure formed by the substance 240 becomes exposed to the thinning. At least one benefit of the thinning is that a package for the semiconductor device can be smaller. For example, a plurality of semiconductor device die can be stacked or otherwise packaged with an increased density when compared to a single die in a package.

As schematically illustrated in FIG. 2H, an exemplary embodiment of a semiconductor wafer at one stage of an exemplary process includes a second support layer 260. In some embodiments the second support layer 260 is permanent, while in other embodiments, the second support layer 260 is removable. For example, in one embodiment the second support layer 260 is provided as a metal, while in another embodiment, the second support layer 260 is formed by an adhesive dicing tape. In these embodiments, the wafer is more resilient and less prone to breaking, in particular during dicing.

In various embodiments, a die that is manufactured in accordance with the techniques disclosed herein include a semiconductor device on a semiconductor substrate. In some embodiments, the semiconductor device includes a micro-electro-mechanical element. The semiconductor substrate includes a mechanical structure. In some embodiments, the semiconductor substrate includes a first plurality of crystalline semiconductor portions and a second plurality of other portions. In some embodiments, the second plurality of other portions differs from the first plurality of crystalline semiconductor portions with respect to a mechanical property. In some embodiments, the second plurality of other portions forms the mechanical structure in the semiconductor substrate. In some embodiments, the semiconductor device comprises at least one circuit element, and the at least one circuit element is separate from the plurality of other portions.

Other embodiments include one or more semiconductor tools or semiconductor processing equipment that is configured to perform embodiments of the method steps disclosed herein.

As used herein, the wording ‘semiconductor device structure’ can relate to a semiconductor device in a finished wafer. The term also encompasses a portion of a semiconductor device that is completed via a manufacturing process, wherein the manufacturing process is not yet completed, that is, the manufacturing of the wafer is not yet completed. In other words, the semiconductor device structure can also include a semiconductor device under construction and, hence, not necessarily a finished semiconductor device.

As used herein, the word ‘exemplary’ means serving as an embodiment, example, instance or illustration. Any aspect or design described herein as ‘exemplary’ is not necessarily to be construed as preferred or advantageous over other aspects or designs. Rather, use of the word exemplary is intended to present concepts and techniques in a concrete fashion. The term ‘techniques’ may refer to one or more devices, apparatuses, systems, methods, articles of manufacture, and/or computer-readable instructions as indicated by the context described herein.

As used herein, the term ‘or’ is intended to mean an inclusive ‘or’ rather than an exclusive ‘or.’ That is, unless specified otherwise or clear from context, ‘X employs A or B’ is intended to mean any of the natural inclusive permutations. That is, if X employs A; X employs B; or X employs both A and B, then ‘X employs A or B’ is satisfied under any of the foregoing instances.

As used herein, the articles ‘a’ and ‘an’ should generally be construed to mean ‘one or more,’ unless specified otherwise or it is clear from the context that they are directed to a singular form.

As used herein, directional terminology, such as ‘top’, ‘bottom’, ‘front’, ‘back’, ‘leading’, ‘trailing’, etc., is used with reference to the orientation of the figure(s) being described. As used herein, terms such as ‘first’, ‘second’, and the like, are also used to describe various elements, regions, sections, etc. and are also not intended to be limiting.

The embodiments herein are described in terms of exemplary embodiments. However, it should be appreciated that individual aspects of the embodiments may be separately claimed and one or more of the features of the various embodiments may be combined. Thus, it is to be understood that the features of the various embodiments described herein may be combined with each other, unless specifically noted otherwise. The order in which the embodiments, methods and processes are described herein is not intended to be construed as limiting, and any number of the described embodiments, methods and processes may be combined. In some instances, well-known features are omitted or simplified to clarify the description of the exemplary embodiments. It is intended that this invention be limited only by the claims and the equivalents thereof.

The inventors intend the described embodiments to be exemplary and not to limit the scope of the appended claims. Furthermore, the inventors have contemplated that the claimed invention may also be embodied and implemented in other ways or in conjunction with other present or future technologies.

What is claimed is:

1. A method, comprising:
providing a semiconductor substrate that is mechanically homogeneous; and
forming a mechanical structure in the substrate.

2. The method of claim 1, further comprising forming an electrical element structure in the substrate.

3. The method of claim 1, wherein forming the mechanical structure comprises:
forming a patterned mask layer over the substrate; and
exposing the patterned mask layer to an etchant to form a plurality of cavities in the substrate.

4. The method of claim 3, further comprising depositing a substance in the plurality of cavities.

5. The method of claim 4, wherein depositing the substance in the plurality of cavities comprises epitaxially depositing the substance in the plurality of cavities.

6. The method of claim 3, further comprising removing the patterned mask layer.

7. The method of claim 2, further comprising planarizing the substrate.

8. A wafer, comprising a semiconductor device on a semiconductor substrate, wherein the substrate includes a mechanical structure.

9. The wafer of claim 8, wherein the substrate comprises a first plurality of crystalline semiconductor portions and a second plurality of other portions, and wherein a mechanical property of the first plurality of crystalline semiconductor portions has a value that is different than the value of the mechanical property of the second plurality of other portions.

10. The wafer of claim 9, wherein the value is a coefficient of elasticity, and wherein the coefficient of elasticity of the second plurality of other portions is greater than the coefficient of elasticity of the first plurality of crystalline semiconductor portions.

11. The wafer of claim 10, wherein the coefficient of elasticity of the second plurality of other portions is equal to or greater than 2% and the coefficient of elasticity of the first plurality of crystalline semiconductor portions is equal to or less than 1%.

12. The wafer of claim 9, wherein the second plurality of other portions form the mechanical structure in the substrate.

13. The wafer of claim 9, wherein the device comprises at least one circuit element, and wherein the at least one circuit element is separate from the second plurality of the other portions.

14. A die, comprising:
a semiconductor device on a semiconductor substrate, wherein the substrate includes a mechanical structure.

15. The die of claim 14, wherein the substrate includes a first plurality of crystalline semiconductor portions and a second plurality of other portions.

16. The die of claim 15, wherein a mechanical property of the first plurality of crystalline semiconductor portions has a value that is different than the value of the mechanical property of the second plurality of other portions.

17. The die of claim 16, wherein the value is a coefficient of elasticity, and wherein the coefficient of elasticity of the second plurality of other portions is greater than the coefficient of elasticity of the first plurality of crystalline semiconductor portions.

18. The die of claim 17, wherein the coefficient of elasticity of the second plurality of other portions is equal to or greater than 2% and the coefficient of elasticity of the first plurality of crystalline semiconductor portions is equal to or less than 1%.

19. The die of claim 15, wherein the second plurality of the other portions form the mechanical structure in the semiconductor substrate.

20. The die of claim 15, wherein the device comprises at least one circuit element, and wherein the at least one circuit element is separate from the second plurality of the other portions.
